(19) United States
(12) Patent Application Publication
(10) Pub. No.: US 2005/0082606 A1
(43) Pub. Date: Apr. 21, 2005

(54) Low K dielectric integrated circuit interconnect structure

(76) Inventors: Stephan Grunow, Dallas, TX (US); Satyavolu S. Papa Rao, Garland, TX (US); Noel M. Russell, Plano, TX (US)

Correspondence Address: TEXAS INSTRUMENTS INCORPORATED, P O BOX 655474, M/S 3999, DALLAS, TX, 75265, US

(21) Appl. No.: 10/689,348

(22) Filed: Oct. 20, 2003

(51) Int. Cl. H01L 29/76

(52) U.S. Cl. 257/330

(57) ABSTRACT

A Low K dielectric layer (20) is formed over a semiconductor (10). Trenches (110, 120) are formed in the dielectric layer (2) and a barrier layer (70) is formed in the trenches. The barrier layer has a thickness of X₁ over the upper surface of the dielectric layer and X₂ on the sidewalls of the trenches where X₁ is greater than X₂. A second barrier layer (130) can be formed over the first barrier layer (70) and copper (100) is formed over both barrier layers to fill the trench.

### FIELD OF THE INVENTION

The invention is generally related to the field of semiconductor processing and more specifically to method for forming a low K dielectric structure.

### BACKGROUND OF THE INVENTION

As the operating speeds of integrated circuits increase, it is becoming increasingly important that any capacitance associated with the metal interconnect lines that form the integrated circuit be reduced. Currently, the metal interconnect lines that connect the various electronic components are embedded in dielectric layers formed above a semiconductor. Parasitic capacitance is introduced into the integrated circuit by the metal interconnect lines and the inter-metallic dielectric (IMD) layers. The capacitance of these structures is proportional to the dielectric constant of the IMD layers that comprise the interconnect structure. One method of reducing the parasitic capacitance is to use dielectric material with a low dielectric constant (i.e. low K dielectric material) to form the IMD layers. An example of such a structure is shown in FIG. 1.

As shown in FIG. 1, a low K dielectric layer 20 is formed above a semiconductor 10. Although omitted from the Figure, any number of intervening layers can be formed between the semiconductor 10 and the dielectric layer 20. In some cases a barrier layer 30 is formed on the low K dielectric layer 20. Most high performance integrated circuits use copper to form the metal interconnects. Copper lines are typically formed using a damascene-type process in which a trench is first formed in the dielectric. The trenches are then filled with copper using a copper electroplating process. As shown in FIG. 1, trenches 36, 36 are formed in the dielectric layer 20. A lined layer 40 is formed in the trench prior to the formation of the copper lines. The liner typically comprises tantalum nitride or other similar material. The low K dielectric material used to form the dielectric layer 20 is a porous material and typically comprises an open pore structure. During the formation of the liner layer 40, the material used to form the liner layer 40 will penetrate into the low K dielectric material resulting in the formation of regions of liner material 50 in the low K dielectric material 20. Following the formation of the liner layer 40, the trenches 34, 36 are filled with copper 45 to form the interconnect lines. In the case of adjacent trenches it is possible that the liner material can form a path 60 that connects the trenches. If the liner material is electrically conductive then an electrical short will exist between the copper lines in the adjacent trenches. This electrical short can cause the integrated circuit to malfunction or cease to operate.

There is therefore a need for a method to form interconnect structures using low K dielectric material that will not result in the formation of electrical shorts. The instant invention addresses this need.

### SUMMARY OF THE INVENTION

The instant invention comprises a structure and method for forming integrated circuit copper interconnects. A low K dielectric layer is formed over a semiconductor. Trenches are formed in the dielectric layer and a first contiguous barrier layer is formed in the trenches using ALD, CVD, or PVD. The thickness of the barrier layer over the upper surface of the low K dielectric layer is X₁ and the thickness of the barrier layer formed along the sidewalls of the trenches is X₂ where X₁>X₂. An optional second barrier layer can be formed over the first contiguous barrier layer. Copper is then used to fill the trenches and form the interconnect structure.

The instant invention offers the advantage of reducing the penetration of the barrier layer material into the low K dielectric. This and other advantages will be apparent to those of ordinary skill in the art having reference to the specification in conjunction with the drawings.

### BRIEF DESCRIPTION OF THE DRAWINGS

In the drawings:

FIG. 1 is a cross sectional diagram showing the creation of electrical shorts in the interconnect structure of an integrated circuit according to the prior art.

FIGS. 2(a)-2(b) are cross sectional diagrams showing an embodiment of the instant invention.

FIG. 3 is a cross sectional diagram showing a further embodiment of the instant invention.

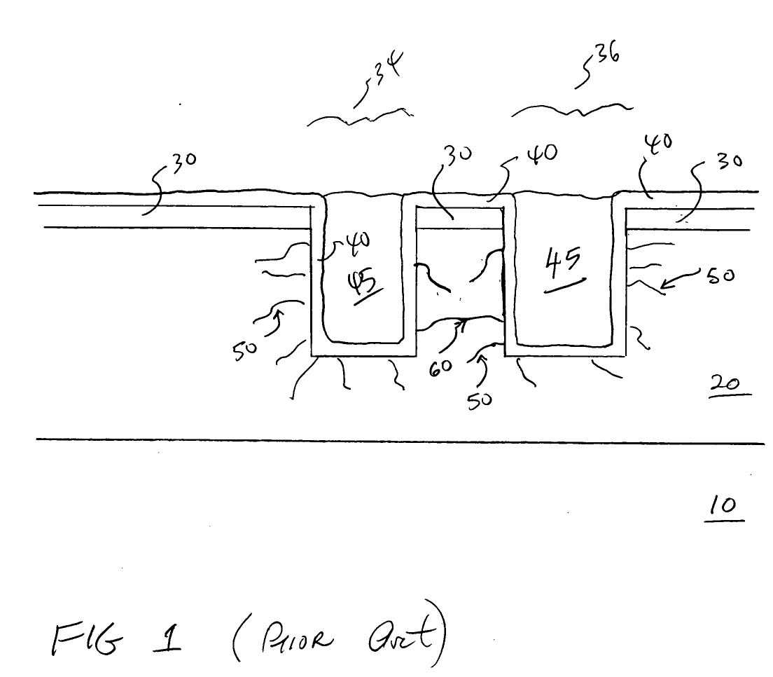

Common reference numerals are used throughout the Figures to represent like or similar features. The Figures are not drawn to scale and are merely provided for illustrative purposes.

### DETAILED DESCRIPTION OF THE INVENTION

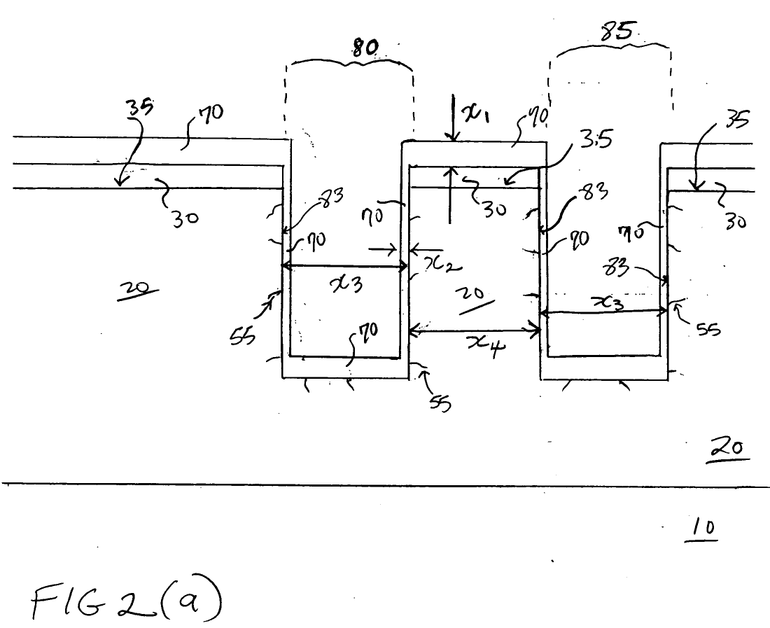

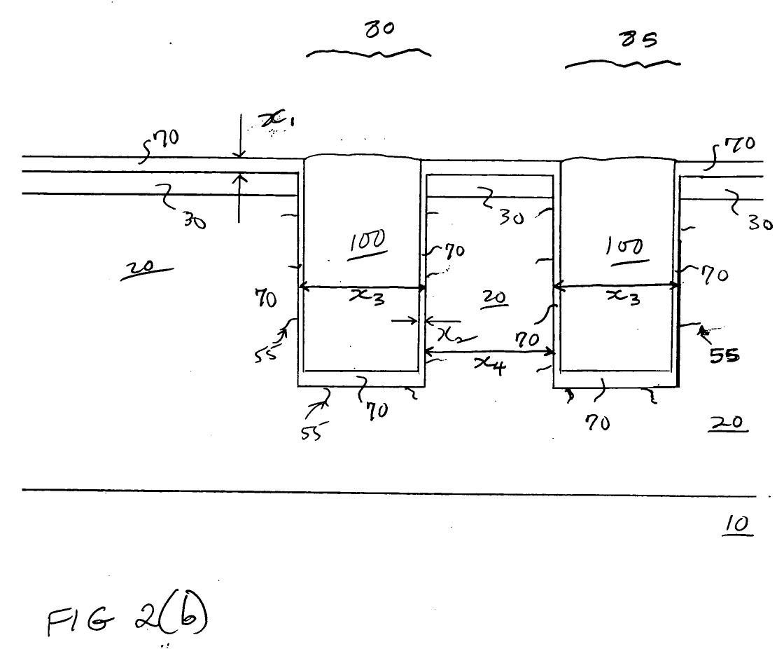

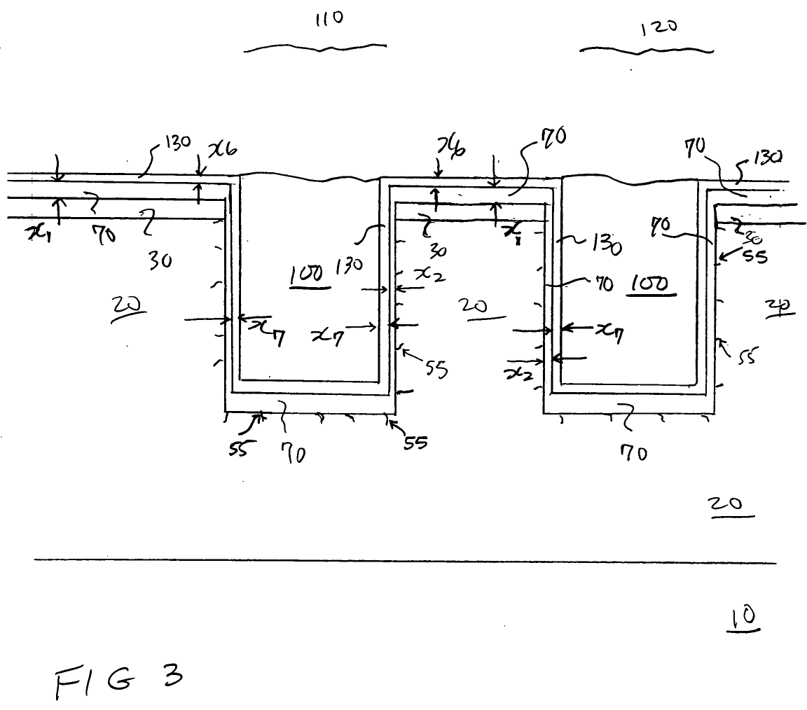

While the following description of the instant invention revolves around FIG. 2(a), FIG. 2(b), and FIG. 3, the instant invention can be utilized in any integrated circuit. The methodology of the instant invention provides an improved interconnect structure and method for integrated circuit formation.

As shown in FIG. 2(a), a low K dielectric layer 20 is formed above a semiconductor 10. Any number of intervening layers can be formed between the semiconductor 10 and the low K dielectric layer 20. Some of these intervening layers will include metal lines and addition dielectric layers. Electronic devices such as transistors, diodes, etc. will be formed in the semiconductor 10 and have been omitted from all the Figures for clarity. Low K dielectric material used to form layer 20 is defined for purposes of this invention as dielectric material with a dielectric constant of approximately ≦3.7. The term low K dielectric is also intended to include dielectric material with a dielectric constant of ≦3.2. The term low K dielectric is also intended to include the class of ultra-low K dielectric material which is defined as dielectric material with a dielectric constant of ≦2.5. Various embodiments of the instant invention can include the following low K and ultra-low K dielectric materials: silsesquioxane (SSQ)-based materials, e.g., methylsilsesquioxane (MSQ), or hydrogensilsesquioxane (HSQ), silica-based materials, e.g., carbon- or fluorine-doped silica glasses, organic-polymer-based materials, amorphous-carbon-based materials, and any other dielectric material that can be made with porous characteristics to reduce the dielectric constant. In general low K dielectric material has pores that can be described as open spaces within the dielectric material. In an embodiment the pores in the low K dielectric layer can comprise an average pore size (or pore diameter) of 1 nm or larger. In a further embodiment the pores in the low K dielectric layer can comprise an average pore size (or pore diameter) of 2 nm or larger.

Formed on the low K dielectric layer 20 is a barrier layer 30. In an embodiment of the instant invention the barrier layer 30 comprises silicon nitride or other suitable dielectric material. Following the formation of the low K dielectric layer 20 and any barrier layer 30, a patterned photoresist is formed on the structure and used as an etch mask during the etching of the dielectric layer 20 and the barrier layer 30 to form the trenches 80, 85.

Following the formation of the trenches 80, 85, a contiguous liner layer (or barrier layer) is formed in the trenches 80, 85. The liner layer or barrier layer can be formed using atomic layer deposition, physical vapor deposition, or chemical vapor deposition methodologies. Shown in FIG. 2(a) is a contiguous liner or barrier layer 70 formed according to an embodiment of the instant invention. In this embodiment a non-conformal barrier layer 70 is formed in which the thickness X₁ is greater than X₂. In an embodiment X₁ represents the thickness of the non-conformal layer 70 formed over the upper surface 35 of the low K dielectric layer 20 and X₂ represents the thickness of the non-conformal barrier layer 70 on a sidewall 83 of the trenches. The liner or barrier layer 70 can comprise titanium, tungsten, tantalum, titanium nitride, tantalum nitride, tungsten nitride, titanium silicon nitride, tantalum silicon nitride, tungsten silicon nitride, ruthenium, iridium, and any alloys that comprise these materials. A number of deposition methods such as chemical vapor deposition (CVD), atomic layer deposition (ALD), and physical vapor deposition (PVD) can be used to form the layer 70.

In the case of CVD (and similar for ALD) processes, the non-conformal layer 70 of the instant invention can be formed by moving from a surface-reaction limited deposition regime to a more mass transport limited deposition regime where, for example, higher substrate temperatures or lower precursor flow rates/partial pressures of the chemical reactants can starve the reactants resulting in the non-conformal layers 70 shown in FIG. 2(a). The reduction (or starving) of reactants used to deposit the barrier layer 70 will result in the limited penetration of the barrier layer material into the pores that exist along the vertical low K dielectric surfaces 83 of the trenches 80, 85. The reduced penetration of the barrier material is indicated 55 in FIG. 2(a) and FIG. 2(b). For PVD processes an increase in the ionic-flux distribution (or wider flux distribution) will result in non-conformal barrier layer 70 formation. In addition, the PVD process can be adjusted to increase the re-sputter component of the deposited barrier liner material onto the sidewalls 83 to paste further barrier material onto the sidewalls for an additional pore-sealing effect.

As shown in FIG. 2(a), adjacent trenches 80, 85 can be formed in the integrated circuit. In an embodiment of the instant invention, the width X₄ of the dielectric separating adjacent trenches is less than or equal to 160 nm. In a further embodiment the width X₃ of the adjacent trenches is each less than or equal to 160 nm. In FIG. 2(a) only two adjacent trenches are shown. The instant invention is not to be limited to two adjacent trenches. The instant invention covers any number of adjacent trenches or via structures formed in low K dielectric material.

In an embodiment of the instant invention, the ratio of X₁ to X₂ (i.e. X₁/X₂) for the case where CVD or ALD is used to form the barrier layer 70 is greater than 3 to 2 (i.e. 3/2). In a further embodiment, the ratio X₁/X₂ for the case where CVD or ALD is used to form the layer 70 is greater than 5/2. In a further embodiment, CVD or ALD can be used to form the barrier layer 70 in the above described ratios when X₃ is less than or equal to 160 nm and/or X₄ is less than or equal to 160 nm.

In a further embodiment of the instant invention, the ratio of X₁ to X₂ (i.e. X₁/X₂) for the case where PVD is used to form the barrier layer 70 is greater than 3 to 1 (i.e. 3/1). In a further embodiment, the ratio X₁/X₂ for the case where PVD is used to form the layer 70 is greater than 8/1. In a further embodiment, PVD can be used to form the barrier layer 70 in the above described ratios when X₃ is less than or equal to 160 nm and/or X₄ is less than or equal to 160 nm.

As shown in FIG. 2(b), copper 100 is used to fill the trenches 80, 85 following the formation of the barrier or liner layer 70. The copper structures can be formed using any known method of copper line formation. In an embodiment of the instant invention, copper is formed in the trenches 80, 85 using an electroplating technique. Any excess copper is removed from the surface of the structure using chemical mechanical polishing (CMP).

Shown in FIG. 3 is a further embodiment of the instant invention. As shown in the Figure, a low K dielectric layer 20 is formed over a semiconductor 10. Adjacent trenches 110, 120 are formed in the low K dielectric layer 20 as described above. The embodiment shown in the Figure should not be limited to two adjacent trenches. The embodiment is intended to apply to a single trench or to any number of adjacent trenches that are formed in the low K dielectric layer 20. A first non-conformal barrier layer 70 is formed in the trenches 110 and 120 using PVD, ALD or CVD. If PVD is used to form the layer 70, the thickness ratio X₁/X₂ is greater than 3/1 in a first embodiment and greater than 8/1 in a second embodiment. If CVD or ALD is used to form the layer 70, the thickness ratio X₁/X₂ is greater than 3/2 in a first embodiment and greater than 5/2 in a second embodiment. The liner or barrier layer 70 can comprise titanium, tungsten, tantalum, titanium nitride, tungsten nitride, tantalum nitride, titanium silicon nitride, tungsten silicon nitride, tantalum silicon nitride, ruthenium, iridium, and any alloys that comprise these materials. Following the formation of the barrier or liner layer 70, a second barrier or liner layer 130 is formed over the layer 70. The second barrier or liner layer 130 can comprise titanium, tungsten, tantalum, titanium nitride, tungsten nitride, tantalum nitride, titanium silicon nitride, tungsten silicon nitride, tantalum silicon nitride, ruthenium, iridium, and any alloys that comprise these materials. In an embodiment, the second barrier or liner layer 130 can be a conformal layer where the layer thickness X₆ is approximately equal to the layer thickness X₇. In a further embodiment the second layer 130 can be a non-conformal layer where the layer thickness X₆ is greater than the layer thickness X₇. In either embodiment the second layer 130 can be formed using ALD, CVD, PVD, or any other suitable technique. If PVD is used to form the second layer 130, the thickness ratio X₆/X₇ is greater than 3/1 in a first embodiment and greater than 8/1 in a second embodiment. If CVD or ALD is used to form the layer 130, the thickness ratio X₆/X₇ is greater than 3/2 in a first embodiment and greater than 5/2 in a second embodiment. In a further embodiment of the instant invention, additional barrier or liner layers can be formed on the second layer 130. The additional layers can be conforming or non-conforming and can comprise titanium, tungsten, tantalum, titanium nitride, tungsten nitride, tantalum nitride, titanium silicon nitride, tungsten silicon nitride, tantalum silicon nitride, ruthenium, iridium, and any alloys that comprise these materials. Following the formation of the second layer 130, and any additional layers, copper 100 is used to fill the trenches 110, 120.

While this invention has been described with reference to illustrative embodiments, this description is not intended to be construed in a limiting sense. Various modifications and combinations of the illustrative embodiments, as well as other embodiments of the invention will be apparent to persons skilled in the art upon reference to the description. For example, in cases where a barrier trench overhang forms on the top surface of the dielectric adjacent to the trench, the overhang can be removed using an insitu barrier etch (e.g., etch in dep/etch/dep (DED) sequence) to “clip-off” the over-deposition. It is therefore intended that the appended claims encompass any such modifications or embodiments.

1. An integrated circuit interconnect structure, comprising:
a low K dielectric layer with an upper surface formed over a semiconductor;
a first trench formed in said low K dielectric layer wherein said trench has sidewalls;
a first contiguous barrier layer formed to a thickness X₁ over said upper surface of said low k dielectric layer and formed to a thickness X₂ on said trench sidewalls wherein X₁ is greater than X₂; and
copper formed over said first contiguous barrier.

2. The integrated circuit interconnect structure of claim 1 further comprising a second trench comprising sidewalls formed in said low K dielectric layer and separated from said first trench by a distance less than 160 nm.

3. The integrated circuit interconnect structure of claim 2 wherein said first contiguous barrier layer is formed to a thickness X₂ on said trench sidewalls of said second trench.

4. The integrated circuit interconnect structure of claim 1 wherein the ratio X₁ to X₂ is greater than 3 to 2.

5. The integrated circuit interconnect structure of claim 3 wherein the ratio X₁ to X₂ is greater than 3 to 2.

6. The integrated circuit of claim 1 further comprising a second contiguous barrier layer formed over said first contiguous barrier layer and beneath said copper.

7. A copper integrated circuit interconnect structure, comprising:
a low K dielectric layer with an upper surface formed over a semiconductor;
a plurality of trenches formed in said low K dielectric layer wherein said plurality of trenches has sidewalls;
a first contiguous barrier layer formed to a thickness X₁ over said upper surface of said low k dielectric layer and formed to a thickness X₂ over said sidewalls of said plurality of trenches wherein the ratio of X₁ to X₂ is greater than 3 to 2; and
copper formed over said first contiguous barrier.

8. The integrated circuit interconnect structure of claim 7 wherein said plurality of trenches are separated from each other by a distance of less than 160 nm.

9. The integrated circuit interconnect structure of claim 7 further comprising a second contiguous barrier layer formed over said first contiguous barrier layer and beneath said copper.

10. The interconnect structure of claim 7 wherein the dielectric constant of the low K dielectric layer is less than or equal to approximately 3.7.

11. A method for forming a copper interconnect structure, comprising:
forming a low K dielectric layer with an upper surface over a semiconductor;
forming a plurality of trenches in said low K dielectric layer wherein said plurality of trenches has sidewalls;
forming a first contiguous barrier layer to a thickness X₁ over said upper surface of said low k dielectric layer and to a thickness X₂ over said sidewalls of said plurality of trenches wherein the ratio of X₁ to X₂ is greater than 3 to 2; and
forming copper over said first contiguous barrier.

12. The method of claim 11 wherein said plurality of trenches are separated from each other by a distance of less than 160 nm.

13. The method of claim 12 further comprising forming a second contiguous barrier layer over said first contiguous barrier layer and beneath said copper.

14. The method of claim 13 wherein the dielectric constant of the low K dielectric layer is less than or equal to approximately 3.7.

15. A method for forming an integrated circuit copper interconnect structure, comprising:
forming a low K dielectric layer with a dielectric constant less than or equal to approximately 3.7 with an upper surface over a semiconductor;
forming a plurality of trenches separated by a distance of less than 160 nm in said low K dielectric layer wherein said plurality of trenches has sidewalls;
forming a first contiguous barrier layer to a thickness X₁ over said upper surface of said low k dielectric layer and to a thickness X₂ over said sidewalls of said plurality of trenches wherein the ratio of X₁ to X₂ is greater than 3 to 2; and
forming copper over said first contiguous barrier.

16. The method of claim 15 further comprising forming a second contiguous barrier layer over said first contiguous barrier layer and beneath said copper.
